(19) United States
(12) Patent Application Publication
(10) Pub. No.: US 2012/0252202 A1
(43) Pub. Date: Oct. 4, 2012

(54) SEMICONDUCTOR MEMORY DEVICES AND METHOD OF MANUFACTURING THE SAME

(76) Inventors: Federica Zanderigo, (US); Maria Gabriella Righini, (US); Giulio Albini, (US); Francesca Sammiceli, (US)

(21) Appl. No.: 13/244,203

(22) Filed: Sep. 23, 2011

(30) Foreign Application Priority Data
Nov. 24, 2010 (KR) 10-2010-0117588

(51) Int. Cl. H01L 21/28

(52) U.S. Cl. 438/592; 257/E21.19

(57) ABSTRACT

The semiconductor memory devices include an interfacial improvement resistance layer is formed between a polysilicon layer and a conductive layer in order to improve interfacial resistance between the polysilicon layer and the conductive layer. The method of manufacturing semiconductor memory devices includes forming a polysilicon layer over a semiconductor substrate, amorphizing the polysilicon layer, and stacking an interfacial improvement resistance layer and conductive layers over the amorphized polysilicon layer.

### CROSS-REFERENCE TO RELATED APPLICATION

Priority to Korean patent application number 10-2010-0117588 filed on Nov. 24, 2010, the entire disclosure of which is incorporated by reference herein, is claimed.

### BACKGROUND

An exemplary embodiment relates to semiconductor memory devices and a method of manufacturing the same and, more particularly, to semiconductor memory devices and a method of manufacturing the same, wherein an interfacial improvement resistance layer is formed between a polysilicon layer and a conductive layer and adequate interfacial resistance between the polysilicon layer and the conductive layer is obtained.

Semiconductor memory devices may include patterns and a number of layers, which are stacked. In particular, if a polysilicon layer and a conductive layer are stacked to form the patterns, an interfacial improvement resistance layer is further formed and adequate interfacial resistance between the polysilicon layer and the conductive layer is obtained.

For example, a TANOS charge trap memory device may have a structure in which a polysilicon layer and a tantalum nitride (TaN) layer are stacked and used as gate electrodes. However, in obtaining adequate interfacial resistance between the tantalum nitride (TaN) layer and the polysilicon layer, an interfacial improvement resistance layer, such as a titanium (Ti) layer, is further formed between the tantalum nitride (TaN) layer and the polysilicon layer. As a result of forming the interfacial improvement resistance layer, titanium (Ti) may be diffused into the polysilicon layer along the grain boundary of the polysilicon layer because of heat generated in a subsequent process.

Furthermore, forming a TANOS charge trap memory device includes a process of patterning the gate electrodes by etching the polysilicon layer, the titanium (Ti) layer, and the tantalum nitride (TaN) layer. The etching method includes a process of forming photoresist patterns and a process of removing the photoresist patterns using a strip process. During the strip process, galvanic corrosion is caused, because Ti diffused in the polysilicon acts as anode and tungsten (W) for the gate electrodes acts as cathode in solution for the strip process. The final result is polysilicon pitting. The subsequent dry etch for gate electrodes formation transfers the defects on silicon substrate of active areas.

### BRIEF SUMMARY

An exemplary embodiment relates to semiconductor memory devices and a method of manufacturing the same, which is capable of decreasing the amount of metal from the interfacial improvement resistance layer that is diffused into the polysilicon layer by first amorphizing the polysilicon layer before depositing the interfacial improvement resistance layer.

A method of manufacturing semiconductor memory devices according to an aspect of the present disclosure includes forming a polysilicon layer over a semiconductor substrate, amorphizing the polysilicon layer, and stacking an interfacial improvement resistance layer and conductive layers over the amorphized polysilicon layer.

A semiconductor memory device according to another aspect of this disclosure includes a polysilicon layer formed over a semiconductor substrate, wherein the polysilicon layer includes injected impurities, an interfacial improvement resistance layer formed on the polysilicon layer, and conductive layers formed over the interfacial improvement resistance layer.

### BRIEF DESCRIPTION OF THE DRAWINGS

FIGS. 1A to 1H are cross-sectional views illustrating a method of manufacturing semiconductor memory devices according to an exemplary embodiment of this disclosure.

### DESCRIPTION OF EMBODIMENT

Hereinafter, an exemplary embodiment of the present disclosure will be described in detail with reference to the accompanying drawings. The drawing figures are provided to allow those having ordinary skill in the art to understand the scope of the embodiment of the disclosure.

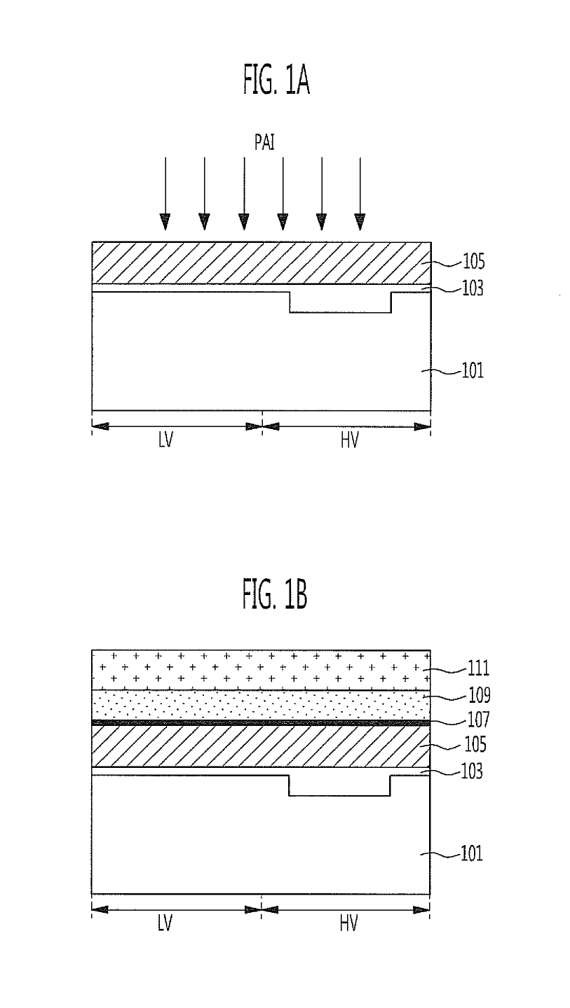

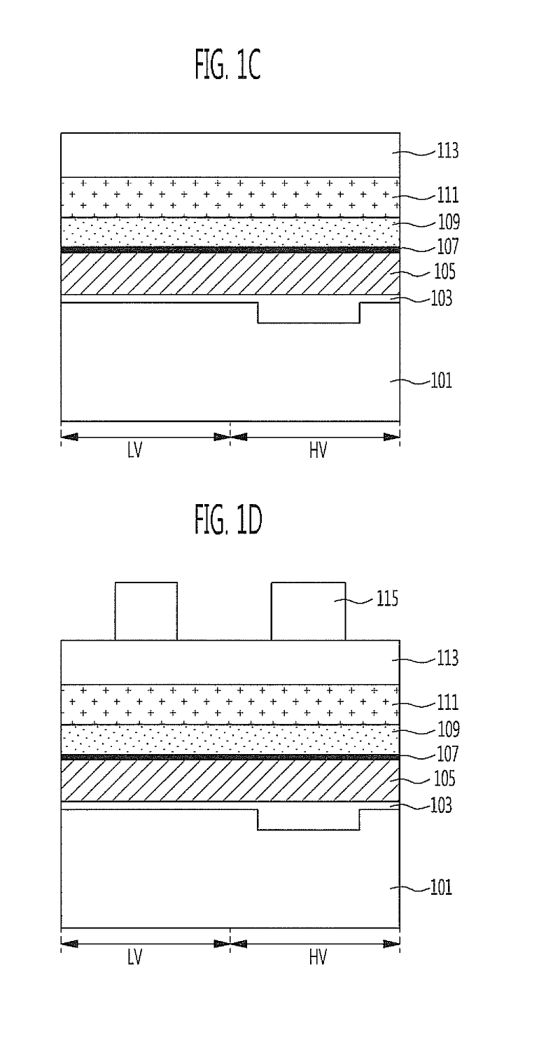

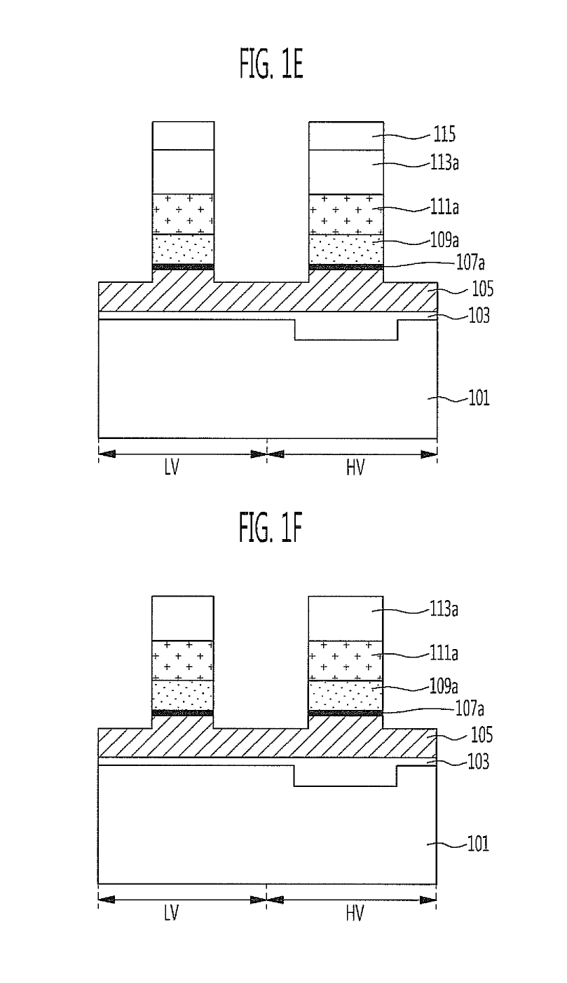

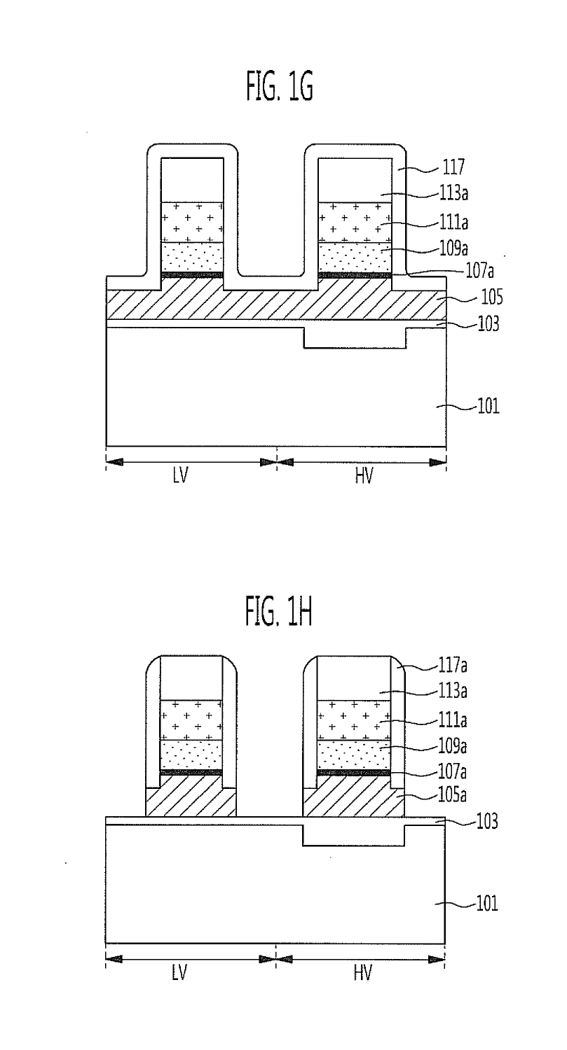

FIGS. 1A to 1H are cross-sectional views illustrating a method of manufacturing semiconductor memory devices according to an exemplary embodiment of this disclosure. In particular, the figures show a peripheral region in which the driving circuits are placed in a semiconductor memory device. The figures also illustrate a process of forming gate electrodes in the peripheral region of the semiconductor memory device.

Referring to FIG. 1A, there is provided a semiconductor substrate 101 defining a high voltage device region HV and a low voltage device region LV. A gate insulating layer 103 is formed on the semiconductor substrate 101. The thickness of the gate insulating layer 103 may vary depending on various environments in which the gate insulating layer is used. For example, the gate insulating layer 103 may be thicker in the high voltage device region HV, where a high-voltage device will be formed, than in the low voltage device region LV, where a low-voltage device will be formed. The gate insulating layer 103 may be formed by oxidizing the semiconductor substrate 101 or by using an oxide layer deposition process. The gate insulating layer 103 may be formed of a silicon oxide (SiO₂) layer.

Next, a stack structure for forming the gate electrodes is formed. First, a polysilicon layer 105 is formed over the gate insulating layer 103. The polysilicon layer 105 may be in a crystalline state in being formed over the gate insulating layer 103. Before the stack is formed, a charge trap layer and a blocking layer may be formed over the gate insulating layer 103 in a cell array region of the semiconductor memory device where memory cells will be placed, although not shown. Furthermore, the stack structure formed over the gate insulating layer 103 may be applied not only in a TANOS charge trap memory device application, but also in NAND flash memory devices having floating gates or in transistors of DRAM devices. In a DRAM device, the transistor may have a similar structure as the stack shown in the low voltage device region LV.

Next, the polysilicon layer 105 is amorphized. As part of the amorphization process, an ion beam collides against silicon atoms in the polysilicon layer 105 through a pre-amorphization implant (PAT) process. The pre-amorphization implant (PAT) process may be performed by implanting more than 1E15 atoms/cm² of arsenic (As) into the polysilicon layer 105 with energy of 20 KeV at a temperature of 25° C. However, the pre-amorphization implant (PAT) process is not limited to the above conditions and may be changed in a plurality of ways in order to amorphize the polysilicon layer 105.

Referring to FIG. 1B, an interfacial improvement resistance layer 107, a first conductive layer 109, and a second conductive layer 111, which form the stack structure for the gate electrodes, are formed over the polysilicon layer 105 in an amorphized state.

The interfacial improvement resistance layer 107] provides adequate interfacial resistance between the first conductive layer 109 and the polysilicon layer 105 The interfacial improvement resistance layer 107 may be formed of a metal layer. The metal layer used as the interfacial improvement resistance layer 107 may include, for example, a titanium (Ti) layer, a tantalum (Ta) layer, or a tungsten (W) layer. Since the interfacial improvement resistance layer 107 is formed over the polysilicon layer 105 in an amorphized state, the amount of material of the interfacial improvement resistance layer 107 that is diffused along the regular grain boundary of the polysilicon layer 105 is decreased.

The first conductive layer 109 formed on the interfacial improvement resistance layer 107 may be formed of a high work function (for example, 4.0 eV or higher) metal nitride layer and obtain adequate back tunneling properties. The high work function metal nitride layer may include, for example, a tantalum nitride (TaN) layer or a titanium nitride (TiN) layer. In the case of the TANOS charge trap memory device, the tantalum nitride (TaN) layer is used as the first conductive layer 109.

The second conductive layer 111 is formed on the first conductive layer 109 and may be formed of a metal layer in order to improve a resistance of the gate electrodes. The metal layer used as the second conductive layer 111 may include, for example, a tungsten (W) layer. If the tungsten (W) layer is used as the second conductive layer 111, a tungsten nitride (WN) layer may be further formed under the tungsten (W) layer as a barrier layer and prevent the diffusion of tungsten (W).

Referring to FIG. 1C, a hard mask layer 113 is formed over the second conductive layer 111. The hard mask layer 113 may be formed of a silicon nitride layer or a silicon oxide layer and may be formed at a temperature of 500° C.

Referring to FIG. 1D, photoresist patterns 115 are formed over the hard mask layer 113. The photoresist patterns 115 may be formed by exposure and development processes.

Referring to FIG. 1E, hard mask patterns 113a are formed by removing the exposed regions of the hard mask layer 113 through an etch process using the photoresist patterns 115 as an etch mask. Next, second conductive layer patterns 111a, the first conductive layer patterns 109a, and the interfacial improvement resistance layer patterns 107a are formed by removing the exposed regions of the second conductive layer 111, the first conductive layer 109, and the interfacial improvement resistance layer 107 through another etch process using the hard mask patterns 113a as an etch mask. According to an example, the etch process removes the exposed regions of the second conductive layer 111, the first conductive layer 109, and the interfacial improvement resistance layer 107 through a dry etch method using the polysilicon layer 105 as an etch stop layer.

Referring to FIG. 1F, the photoresist patterns 115 are removed by a strip process. According to an example, the strip process is performed by a wet etch process, and it is used to prevent oxidization of any metal layer susceptible to oxidization, such as the tungsten (W) layer. By preventing oxidization of the metal layer, an additional cleaning process for removing a metal oxide layer needs not to be performed, and the process is more efficient.

Referring to FIG. 1G, a spacer layer 117 is deposited over an entire structure, including sidewalls of the patterns 111a, 109a, and 107a for the gate electrodes, and the exposed surface of the polysilicon layer 105. The spacer layer 117 may be formed using a furnace deposition process. The spacer layer 117 may be formed of a nitride layer, not an oxide layer, in order to prevent the oxidization of any metal layer, such as a tungsten (W) layer, that is susceptible to be oxidized. The polysilicon layer 105 in an amorphized state is recrystallized by heat that is generated during the process of depositing the spacer layer 117. The polysilicon layer 105 in an amorphized state may also be recrystallized by heat that is generated in a subsequent process, in addition to the deposition process of the spacer layer 117. Furthermore, a silicide layer is formed at the interface of the interfacial improvement resistance layer 107 and the polysilicon layer 105 during deposition the spacer layer 117. The silicide layer provides an ohmic behavior to decrease the resistance.

Referring to FIG. 1H, the surface of the polysilicon layer 105 and the surface of the hard mask layer patterns 113a are exposed by etching the spacer layer 117 using an etch process, such as etch-back or blanket etch, thereby forming spacers 117a on the sidewalls of the hard mask patterns 113a and the patterns 111a, 109a, and 107a. Next, polysilicon patterns 105a for the gate electrodes are formed by etching the exposed surface of the polysilicon layer. According to an example, the exposed surface of the polysilicon layer is etched using a dry etch process having etch selectivity for an oxide layer.

In this disclosure, before the interfacial improvement resistance layer is deposited, the polysilicon layer is amorphized.

As described above, before the interfacial resistance improvement layer is deposited, the polysilicon layer is amorphized in order to prevent metal, included in the interfacial improvement resistance layer, from being diffused into the polysilicon layer along the grain boundary of the polysilicon layer during the hard mask deposition step.

What is claimed is:

1. A method of manufacturing semiconductor memory devices, comprising:
forming a polysilicon layer over a semiconductor substrate;
amorphizing the polysilicon layer; and
stacking an interfacial improvement resistance layer and conductive layers over the amorphized polysilicon layer.

2. The method of claim 1, wherein the polysilicon layer is amorphized using a pre-amorphization implant (PAT) method.

3. The method of claim 1, wherein the interfacial improvement resistance layer is made of titanium (Ti), tantalum (Ta), or tungsten (W).

4. The method of claim 1, wherein the conductive layers comprise:
a back tunneling improvement layer formed of a metal nitride layer having a high work function, and
a resistance improvement layer formed of a metal layer.

5. The method of claim 4, wherein the back tunneling improvement layer is a tantalum nitride (TaN) layer or a titanium nitride (TiN) layer.

6. The method of claim 4, wherein the resistance improvement layer is a tungsten (W) layer.

7. The method of claim 6, wherein an anti-diffusion layer is formed of a tungsten nitride (WN) layer and is further formed under the resistance improvement layer.

8. The method of claim 1, further comprising:
stacking a hard mask layer and photoresist patterns over the conductive layers;
patterning the hard mask layer by an etch process using the photoresist patterns as an etch mask;
removing exposed regions of the conductive layers and the interfacial improvement resistance layer by using the patterned hard mask layer as an etch mask;
removing the photoresist patterns; and
removing exposed regions of the amorphized polysilicon layer.

9. The method of claim 8, further comprising forming spacers on sidewalls of the patterned hard mask layer, the conductive layers, and the interfacial improvement resistance layer before removing the exposed regions of the amorphized polysilicon layer.

10. The method of claim 9, wherein the spacers are formed of a nitride layer.

11. The method of claim 9, wherein the amorphized polysilicon layer is recrystallized when forming the spacers.

12. A method of manufacturing semiconductor memory devices, comprising:
forming a polysilicon layer over a semiconductor substrate;
amorphizing the polysilicon layer by a process including implanting impurities into the polysilicon layer;
stacking an interfacial improvement resistance layer over the amorphized polysilicon layer; and
recrystallizing the amorphized polysilicon layer.

13. The method of claim 12, wherein the polysilicon layer is crystalline before performing the amorphizing of the polysilicon layer.

14. A semiconductor memory device, comprising:
a polysilicon layer formed over a semiconductor substrate, wherein the polysilicon layer includes injected impurities;
an interfacial improvement resistance layer formed on the polysilicon layer; and
conductive layers formed over the interfacial improvement resistance layer.

15. The semiconductor memory device of claim 14, wherein the interfacial improvement resistance layer is made of titanium (Ti), tantalum (Ta), or tungsten (W).

16. The semiconductor memory device of claim 14, wherein the conductive layers comprise:
a back tunneling improvement layer formed of a metal nitride layer having a high work function, and
a resistance improvement layer formed of a metal layer.

17. The semiconductor memory device of claim 16, wherein the back tunneling improvement layer is a tantalum nitride (TaN) layer or a titanium nitride (TiN) layer.

18. The semiconductor memory device of claim 16, wherein the resistance improvement layer is a tungsten (W) layer.

19. The semiconductor memory device of claim 18, wherein an anti-diffusion layer is formed of a tungsten nitride (WN) layer and is further formed under the resistance improvement layer.
